(19) United States
(12) Patent Application Publication
(10) Pub. No.: US 2017/0345896 A1
(43) Pub. Date: Nov. 30, 2017

(54) FIELD EFFECT TRANSISTOR STRUCTURES USING GERMANIUM NANOWIRES

(71) Applicant: INTEL CORPORATION, SANTA CLARA, CA (US)

(72) Inventors: RASEONG KIM, HILLSBORO, OR (US); UYGAR AVCI, PORTLAND, OR (US); IAN YOUNG, PORTLAND, OR (US)

(21) Appl. No.: 15/525,885

(22) PCT Filed: Dec. 24, 2014
(86) PCT No.: PCT/US2014/072341

§ 371 Date: May 10, 2017

(51) Int. Cl. H01L 29/06; H01L 29/775; H01L 29/66; H01L 29/423; H01L 29/16; H01L 29/786; B82Y 10/00

(52) U.S. Cl. CPC H01L 29/0673; H01L 29/78696; H01L 29/775; B82Y 10/00; H01L 29/42392; H01L 29/16; H01L 29/66439

(57) ABSTRACT

Field effect transistor structures are described that are formed using germanium nanowires. In one example, the structure has a germanium nanowire formed on a substrate along a predetermined confinement orientation, a first doped region of the nanowire at a first end of the nanowire to define a source, a second doped region of the nanowire at a second end of the nanowire to define a drain, and a gate dielectric formed over the nanowire between the source and the drain.

### FIELD

The present description relates to the field of metal oxide semiconductor devices and in particular to such devices using germanium as a current channel.

### BACKGROUND

The transistors in integrated circuit systems are made increasingly smaller. The reduced size of the transistor decreases the amount of conductive material that is able to carry a current or sustain a voltage. For MOS (Metal Oxide Semiconductor) devices, the amount of current is described in terms of the number of and movement of electrons in n-type MOS (nMOS) device channels and the number of and movement of positively charged holes in p-type MOS (pMOS) device channels.

For a MOSFET (Metal Oxide Semiconductor Field Effect Transistor) device, the channel carries the current (charge) from a source at one end to a drain at the other end. The current (charge) flow is regulated by a gate which is applied over the channel or around the channel body. In order to further reduce the size of MOSFETs in an integrated circuit, a smaller (shorter) channel with higher current per unit width is required. High carrier (electron or hole) mobility is a key element in assessing the usefulness of the charge carrying current channel in bulk MOSFETs.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is diagram of constant energy surfaces for the conduction band of bulk germanium.

FIG. 2 is a side view diagram of a germanium nanowire.

FIG. 3 is a side view diagram of a MOSFET constructed using a germanium nanowire according to an embodiment.

FIG. 4 is a cross-sectional side view diagram of a MOSFET constructed using a germanium nanowire according to an embodiment.

FIG. 5A is a diagram of Γ-valley confinement in a germanium nanowire according to an embodiment.

FIG. 5B is a diagram of two-dimensional confinement of the Γ-valley confinement of FIG. 5A according to an embodiment.

FIG. 6A is a diagram of constant energy surfaces in a confinement zone for a germanium nanowire according to an embodiment.

FIG. 6B is a diagram of two-dimensional confinement of the constant energy surfaces of FIG. 6A according to an embodiment.

FIG. 7 is a graph of conduction band E-k values for a circular germanium nanowire according to an embodiment.

FIG. 8 is a graph of density-of-states for a circular germanium nanowire according to an embodiment.

FIG. 9A is a graph of drain current vs. gate voltage for different confinements of a germanium nanowire nMOSFET according to an embodiment.

FIG. 9B is a graph of conduction band E-k values of a germanium nanowire nMOSFET according to an embodiment.

FIG. 10 is a cross-sectional side view diagram of germanium nanowire n and p-type MOSFETs fabricated on a single substrate according to an embodiment.

FIG. 11 is a process flow diagram of forming a MOSFET device according to an embodiment.

FIG. 12 is a block diagram of a computing device incorporating a die with Ge channel MOSFETs according to an embodiment.

### DETAILED DESCRIPTION

In scaled devices, CMOS (Complementary MOS) devices, such as MOSFETs, the semiconductor body may also be scaled along with the overall size of the CMOS device. This may result in a thin body or nanowire structure in order to maintain good electrostatic properties for a MOSFET with a short channel length. In such structures, the effects of quantum confinement due to the scaled body and ballistic transport due to the short channel become very important. A high mobility material based on its bulk properties may not result in high current drivability in scaled devices, where sufficient bulk dimension is not available so that the channel material properties are significantly different than in bulk form.

For example, while group III-V semiconductor materials have high electron mobility due to their light electron effective mass (me*), they have low electron density-of-states (DOS), also due to their light me*. For extremely small nMOSFETs, the low electron DOS of group III-V semiconductor materials may result in a significant loss of channel charge compared with other high-DOS materials such as Si. As a result, the drive current improvement may not be as much as the mobility improvement would suggest. This may be referred to as a DOS bottleneck. The drive current may actually be worse than for Si because the charge is smaller. For extremely small pMOSFETs, the low hole mobility of group III-V materials may limit performance. Ge on the other hand has a high hole mobility. In addition, there is a compatibility issue when using III-V semiconductor materials for nMOS and Ge for pMOS in the same die or vice versa. These different materials require different processes and different materials for fabrication.

By using a Ge nanowire to fabricate an nMOSFET, the compatibility issues with Ge pMOS are overcome. In addition, quantum confinement orientations may be used to improve current drivability for Ge nanowire nMOS.

The drive current I_{D} in a MOSFET may be expressed as the charge density Q times the carrier velocity v. To increase I_{D}, either Q or v or both may be increased. To increase v, a small carrier effective mass (m*) is desired. While Q may be dominated by a gate oxide capacitance Cₒₓ in large scale devices, the effect of the channel material and its DOS become increasingly important as the device scaling continues. To maintain a high Q in scaled devices, a high DOS or quantum capacitance C_{Q} and a high overall capacitance, which is the result of Cₒₓ and C_{Q} series, may be used. The DOS depends on two quantities, m* and the valley degeneracy gᵥ. A larger m* and gᵥ give a larger DOS. However, since a smaller m* provides a higher v, it may be better to keep m* small. Both Q and v may be increased simultaneously by increasing gᵥ while keeping m* small.

Ge nanowires (NWs) with a <110> transport direction may be used to provide a high Q and v for nMOSFETs by selecting appropriate quantum confinements of the L- and Gamma-valleys in the conduction band. Ge NW pMOSFETs with the same type of quantum confinement may also deliver good current drivability. Fabricating n and pMOSFETs with Ge NW provides a material-compatible, Ge-based CMOS wafer fabrication technology.

Ge nanowire (NW) nMOSFETs when fabricated with optimum confinement orientations provide high mobility (carrier velocity), high charge density, and therefore high current. In other words, Ge NW with an appropriate confinement provides two desirable attributes: a high carrier velocity which correlates to mobility; and a high charge density Q. These two attributes together result in high current flow through the channel. Although Ge is not the material with the highest electron mobility in the bulk state, Ge NW nMOSFETs with <110> transport, fabricated with appropriate quantum-confined band structures, delivers a higher drive current than, for example, InAs or Si.

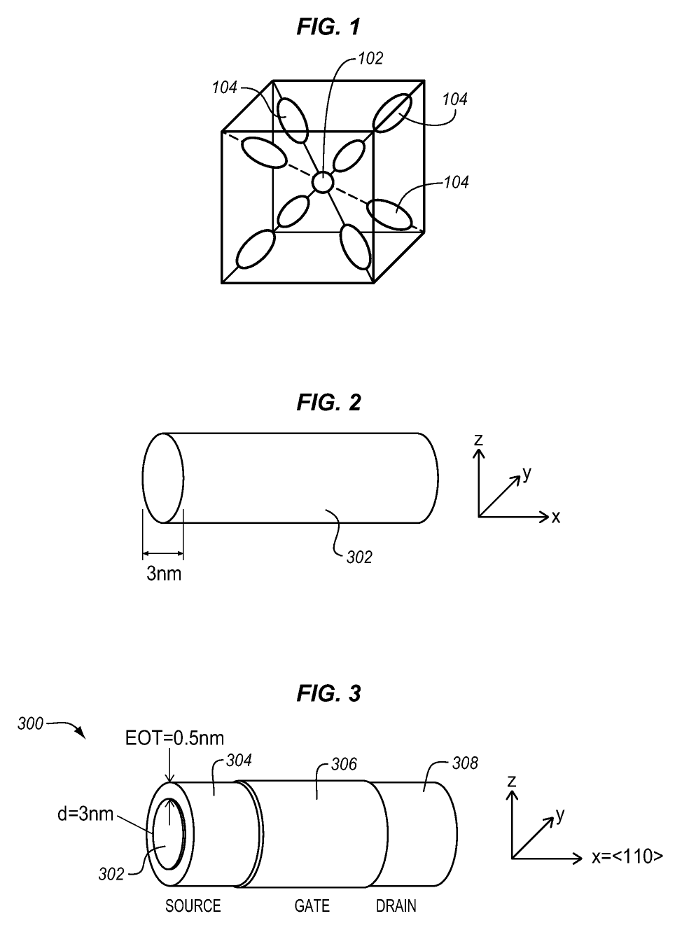

FIG. 1 is a diagram of constant-energy surfaces for the conduction band (CB) of Ge bulk material. The L-valleys are the lowest 104 with the Γ-valley 102 being the next. The energy levels of Γ- and L-valleys are not so different, so both valleys are important for Ge n-type device characteristics.

FIG. 2 is a diagram of an example Ge NW. The NW is shown as cylindrical with a circular cross-section, however, the invention is not so limited. The nanowire core 302 of the device may have a cross-section that is a semicircle or any other part of a circle. The cross-section may be polygonal, such as rectangular, square, or any other multiple sided shapes with flat or rounded sides. The particular cross-sectional shape may be adapted to suit a particular fabrication process or restraints from other nearby structures.

The germanium nanowire is referred to as a nanowire because it has a cross-sectional diameter that is measured in nanometers and because it has a length greater than its diameter. The diameter in this example is indicated as 3 nm. The diameter may be smaller as permitted by fabrication technology and limited by surface effects. For extremely thin nanowires, the surface effect of the reconstruction of atoms at the surface may change the material properties and limit the suitability of the nanowire for a current channel. A diameter as small as three times the lattice constant, for example 1.5-2 nm may be used without significant impact from surface effects. The diameter may be larger up to 10 nm. Diameters larger than 10 nm may be affected by bulk effects. In other words, as the nanowire is made thicker it starts to behave more like bulk material.

The length of the nanowire may be from 3 to 10 times the diameter. For shorter lengths, short channel effects may limit the gate controllability of the current flow and switching performance of a MOSFET. Longer channel lengths provide greater electrostatic performance but require more surface on the die to be implemented and may suffer from higher channel resistance due to carrier scattering. Accordingly, performance and size appear to be optimized for lengths of 3 to 5 times the diameter of the NW. The particular choice of length may depend on the substrate, the gate oxides, the desired current and voltage characteristics and other factors.

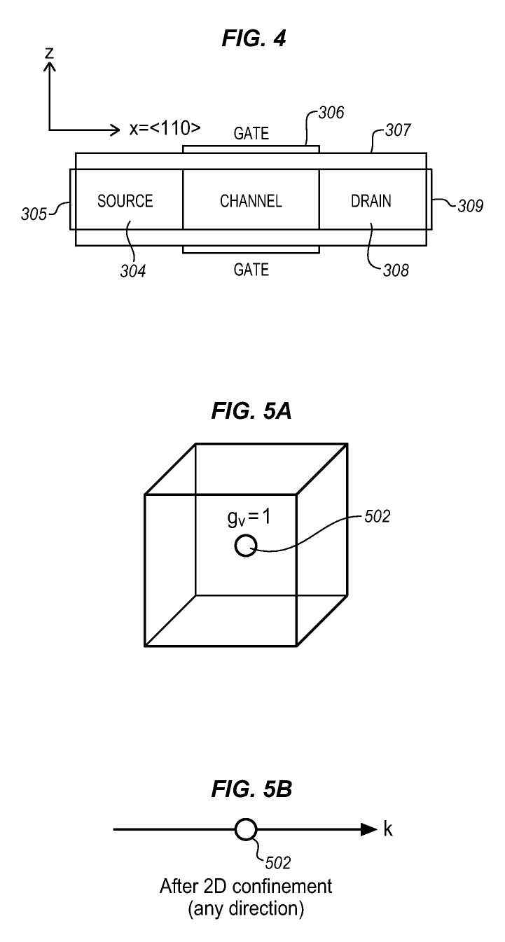

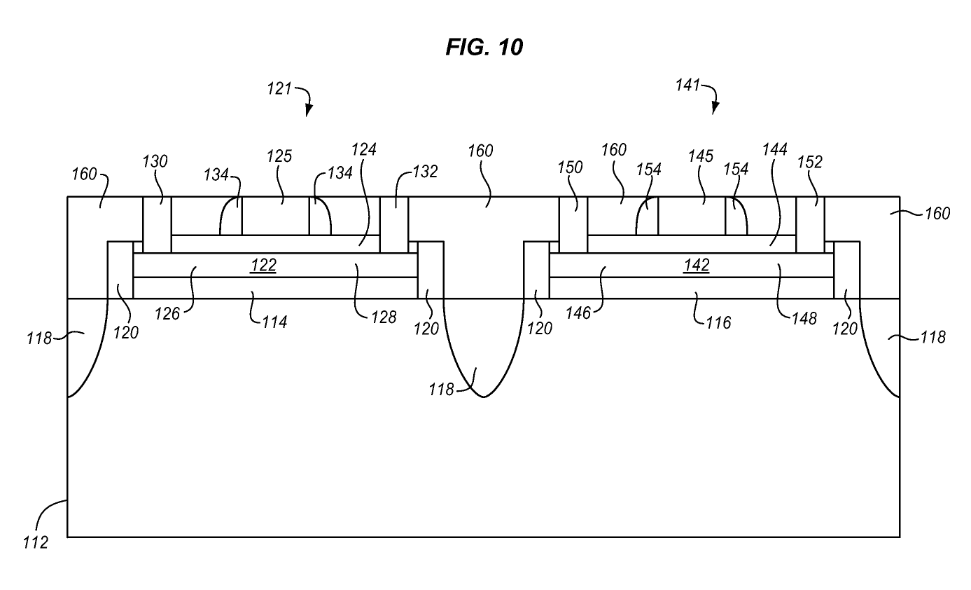

FIG. 3 is a diagram of an example Ge NW MOSFET 300 incorporating the germanium nanowire of FIG. 2. The NW 302 has a transport direction (x) and 2D confinement directions (y and z) in the plane of the diagram. The MOSFET 300 has a central Ge nanowire 302 where a source and a drain are defined as highly doped regions 304, 308, respectively connected to metal contacts 305, 309, respectively at opposite ends as shown in the cross-sectional view of FIG. 4. The metal contacts are positioned at the ends of the nanowire to cover the circular cross-section. While the metal contacts are shown as having a matching circular cross-section, the contacts may have any desired shape that provides a connection to the highly doped regions and allows for an external connection. FIG. 10 shows a different physical configuration for the metal contacts in the form of vertical electrodes allowing connections to higher layers over the MOSFET.

In between the source and the drain the Ge nanowire is surrounded by a gate oxide 307 dielectric layer, sheath, housing or shell. A terminal 306 is provided on top of that for control of current flow from the source to the drain. A similarly shaped dielectric layer, sheath, housing or shell may be extended to the source 304 and the drain 308 regions. The gate dielectrics may be formed of oxides, such as SiO₂ or any of a variety of other suitable dielectrics of higher dielectric constant, depending on the particular application. An “equivalent oxide thickness” (EOT) of 0.5 nm is sufficient for a NW of 3 nm, however, the invention is not so limited. The oxide region 307 may be extended to the source and the drain region as shown, but the invention is not so limited.

The gate dielectrics are shown as cylindrical and completely surrounding the NW at the core of the device, however, the invention is not so limited. The surrounding dielectric gate structures may completely or only partially surround the Ge core. The Ge NW core 302 may be fabricated over another material and covered with the gate dielectrics, or the gate dielectrics may first be applied and then covered with some other isolation material.

FIG. 5A is a diagram of Γ-valley confinement in a Ge NW such as that of FIGS. 3 and 4. The Γ-valley is projected at k=0, regardless of the confinement directions. The valley degeneracy (gᵥ) per ellipsoid (within a first Brillouin zone (BZ)), is 1 for the Γ-valley as shown in FIG. 5B. The confinement is projected to a point 502 at k=0 with gᵥ=1 and light m* regardless of directions. FIG. 5B is a diagram of the same point at gᵥ=1 with energy in the one allowed x direction with k.

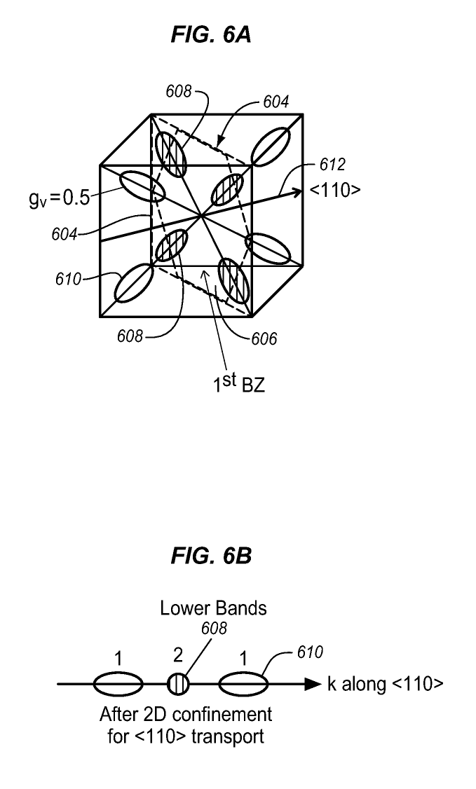

FIG. 6A is a diagram of L-valley confinement within a confinement plane 604 in NWs with a <110> transport. Low energy bands 608 are projected at k=0 with gᵥ=2 and light m*. Heavy-m* bands 610 are also projected, but have less effect due to the high energy levels.

FIG. 6A shows what happens to the L-valleys, particularly for x=<110>. As shown the gᵥ per ellipsoid 608 within the first BZ 606 is 0.5 for the L-valley. The 2D confinement plane 604 for x=<110>612 includes two L-valleys within the first BZ. These valleys have large confinement mass, due to the longitudinal mass of the L-valley, and small transport mass, due to the transverse mass of the L-valley. This results in the low energy bands 608 projected at k=0 with gᵥ=2 and light effective mass (m*). The other two L-valleys 610 are projected at non-zero k-points with heavier m*, but they have less effect because they lie at higher energies.

FIG. 6B shows theses energy bands both low energy 608 at gᵥ=2 and high energy 610 at gᵥ=1 with transport toward k in a <110> transport structure. As shown in FIGS. 5A, 5B, 6A, and 6B, the nanowire structures combined with quantum confinements of Γ- and L-valleys are suitable for extremely scaled MOSFETs such as that of FIG. 4.

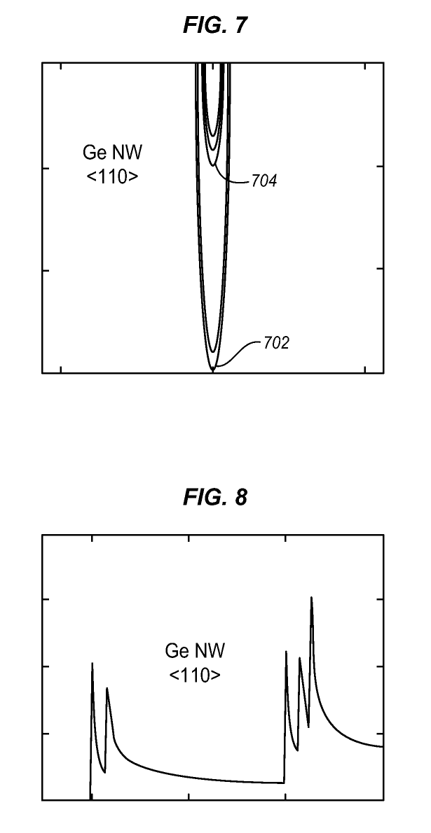

FIG. 7 is a graph showing electron energy on the vertical axis against k on the horizontal axis. These are CB (Conduction Band) E-k results calculated using an atomistic tight-binding model for circular NWs with a diameter (d) of 3 nm for x=<110>. Band parameters (gᵥ and m*) may be extracted from this model to aid in determining performance characteristics for MOSFETs with different dimensions and confinements. When quantum confined for the <110> transport, Ge L-valleys 702, 704 give low bands with gᵥ=2 and a small me*. In the energy levels of interest, the L- and Γ-valleys of Ge may give additional bands with gᵥ=2 and gᵥ=1, respectively, for which all me* are small.

FIG. 8 is a graph showing DOS (Density-of-States) on the vertical axis against energy on the horizontal axis. The higher gᵥ of Ge<110> NW CB results in a much improved electron DOS compared to other types of nMOSFET structures such as group III-V NW structures. This helps to remove the DOS bottleneck associated with very small MOSFET structures. Meanwhile, the me*'s of Ge<110> NW are still small, which will maintain an improvement in the carrier injection velocity compared with other types of nMOSFET structures such as Si NW. The high DOS and high carrier velocity allow for an improvement in the drain current vs. the drain voltage compared to other nMOSFET materials.

The Ge NW, when optimally quantum-confined for <110> transport (with a <110> NW), shows a high carrier velocity without a significant channel charge loss. This further contributes to a high drain current.

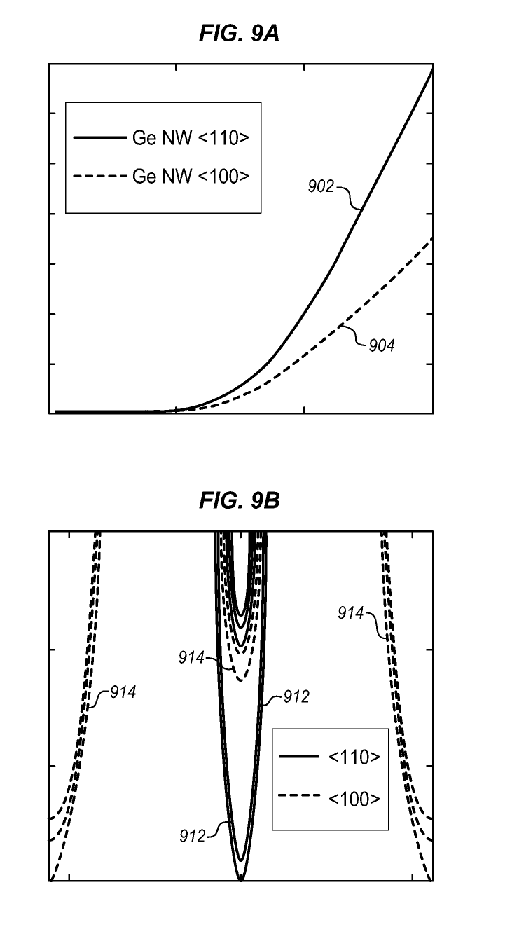

FIG. 9A is a graph of drain current I_{D} on the vertical axis against gate voltage V_{G} on the horizontal axis for a fixed drain voltage V_{D} for an example Ge NW MOSFET of the type described above. These simulation results show results for both a <110> direction 902 and for a <100> transport direction 904.

FIG. 9B is a graph of energy against k similar to that of FIG. 7 showing a curve 912 for the <110> transport direction and a curve 914 for the <100> transport direction. These curves are based on the same CB E-k of a Ge NW with a cross-sectional diameter of 3 nm as in the other examples.

As shown, the I_{D} degrades significantly for the <100> transport as compared to the <110> transport. A MOSFET based on Ge<110> NW has a large gᵥ (high DOS) and a light me* (high carrier velocity), which give an I_{D} improvement. For Ge<100> NW, the lowest bands with large gᵥ (near the zone edge) are still coming from the L-valley, improving the DOS. The me*, however, is much heavier, as may be indicated by a wider E-k parabola, than in <110> NW. The <100> quantum confinement significantly degraded the carrier velocity.

While the examples and performance details described above are based on nMOSFET, for typical devices, both nMOSFET and pMOSFET are required. The fabrication cost of any complex circuitry is reduced when the n and p processes are compatible and can be performed simultaneously. The best process compatibility with a Ge NW nMOSFET with <110> transport, would be with a Ge NW pMOSFET also with the <110> transport direction. This may also be the best choice for performance as well.

The DOS bottleneck discussed above is not normally an issue for pMOSFETs because the valence bands (VB), which are conducting for the pMOSFETs, include many bands with high degeneracy. Instead, the hole effective mass (mh*) is more important. A light mh* helps to improve the pMOSFET I_{D}. Ge, which gives a high bulk hole mobility, may also give a high I_{D} in a scaled pMOSFETs because both hole mobility and I_{D} are closely related to the lighter mh* of Ge as a conducting material.

As to the confinement orientation, the VB minima are at the F-point for bulk Ge. In 2D-confined NWs, however, due to the band non-parabolicity and spin-orbit coupling, the band splitting and mh* depend on the confinement orientations. The mh* of <110> Ge NW is lighter than that for <100> Ge NW. As a result, <110> Ge NW pMOSFETs deliver a higher I_{D}. Ge <110> NW pMOSFET provides high performance due to the small mh* values.

FIG. 10 is a cross-sectional side view diagram of a portion of a semiconductor structure incorporating a Ge NW nMOSFET and a Ge NW pMOSFET in a single structure as described herein. The structure has a substrate 112 formed of any of a variety of different materials. This include silicon which may be formed from, or grown from poly-crystal silicon, single crystal silicon, or various other suitable technologies for forming a silicon base or substrate, such as a silicon wafer. An oxide layer 114, 116 such as silicon dioxide may be formed over the substrate. The substrate may alternatively be formed of other group IV or III-V semiconductor wafers, of such layers grown upon a silicon wafer, of insulating layers such as sapphire or an oxide layer of a Silicon-On-Insulator (SOI) wafer, or of a variety of other dielectric layers. The Ge NW nMOSFETs and pMOSFETs may be built without an underlying p-type well and n-type well by isolating the NW body from the substrate using the dielectric layers 114, 116.

The substrate may be treated in any of variety of ways. In some embodiments, the substrate or base 112 may be doped to form p-type well and an n-type well as desired or for other components (not shown) on the other side. In the illustrated example, the Ge NW structures are isolated from any doping by the oxide layers. While only two MOSFET devices are shown, the diagram is intended to be representational only. An integrated circuit may have thousands or millions of MOSFETs or only a few depending on the application.

Shallow trench isolation (STI) areas 118 may be formed between the devices and a corresponding n-type 121 or p-type 141 transistor is formed over the substrate. The n-type transistor is formed by a Ge NW 122 over the dielectric layer 114. The NW extends across a top surface of the dielectric and is three or more times longer than its diameter. Each end is bounded by dielectrics 120, such as high k dielectrics. A source region 126 is formed at one end by doping the nanowire and a drain 128 is formed at the other end by doping the nanowire. A dielectric 124 such as an oxide layer surrounds all or part of the NW from one end to the other and also serves as a gate dielectric. An electrode 130, 132 is formed over the source and drain, respectively, to allow the source and drain to be coupled to other components (not shown).

In the illustrated example, the NW is shown as having a substantially rectangular cross-section as is easily generated using convention photolithography techniques. The electrodes are formed as columns, pillars, or vias over the NW layer using photolithography, etching, or drilling techniques. The dielectric layer 124 is shown as both above and below the NW and may surround the NW on all four sides depending on the nature of the well and surrounding materials.

The center of the NW 122 is surrounded in whole or in part by the gate dielectric 124 over which a gate electrode 125 is formed. The gate electrode is shielded by spacers 134 on either side and extends away from the NW to allow the gate electrode to be coupled to a control voltage (not shown) or any other signal depending on the intended use of the device. The entire structure is shielded in an insulating and protection layer 160 and additional wiring layers and device layers maybe formed over the MOSFETs to complete the device.

Similarly the p-type transistor is also formed using a Ge NW 142 over an oxide layer 116. The Ge NW is partially or completely enclosed by a source dielectric 146 at one end, a drain dielectric 148 at the other end and a gate dielectric 144 between the source and drain. The source and drain and the NW structure are terminated with dielectric structures 120 at each end. The gate electrode 145 is isolated by spacers 154 and the source and drain are provided with electrodes 150, 152 to connect the device to other devices. The entire structure is covered in the same isolation layer 160 as the n-type device 121. While the illustrated devices are transistors many other semiconductor devices may be formed on the same substrate using similar techniques.

In some embodiment, an n-well or p-well may connect to either or both of the Ge nanowires 122, 142 if the nanowire is not completely surrounded by the gate dielectric 124, 144. In such cases the gate may surround the NW on three sides, two sides or just the top side.

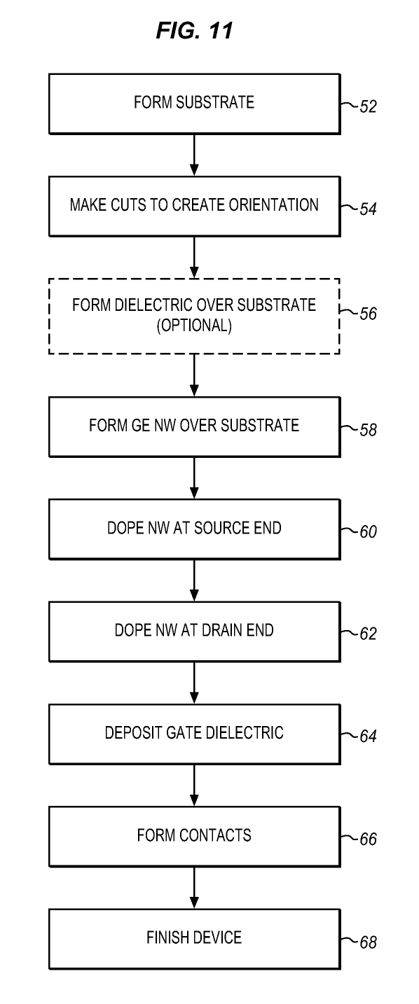

FIG. 11 is a process flow diagram of forming a MOSFET device on a substrate as described herein. At 52 a substrate is formed having a (100) surface. The substrate may be formed from or grown from a silicon base or from a variety of other materials including group IV or group III-V materials. At 54 the substrate a <110> cut is made on the substrate to from a predetermined orientation for the MOSFET device.

At 56 a dielectric is optionally formed on the substrate. This may be used to isolate the device from a doped well or from other characteristics of the substrate. The nature and use of the dielectric may be determined based on the nature of the substrate.

At 58 a germanium nanowire is formed on the substrate along a predetermined confinement orientation. The germanium nanowire may be formed in any of a variety of different ways including by deposition over patterned photolithography masks. Due to the small size of the nanowire, many nanowires may be formed simultaneously at different locations on the substrate.

At 60 a first region of the nanowire at one end is doped to define a source for the MOSFET. At 62, the other end of the nanowire is doped to define the drain and at 64 a gate dielectric is formed, for example by deposition, over the nanowire between the source and the drain to form the gate. The particular size structure, position, and number of doped regions may be modified to form a variety of different MOSFET-type devices.

At 66 contacts are formed at the source, drain, and gate to allow connection to and use of the device. The contacts may be formed by etching and filling, by drilling and plating, or in any of a variety of other ways. As shown in the above figures, the contacts may cover the ends of the nanowire or be formed over the ends of the nanowires, depending on the particular device being formed. At 68, the device is finished with electrodes, isolation layers, additional contacts or any structures that may be desired.

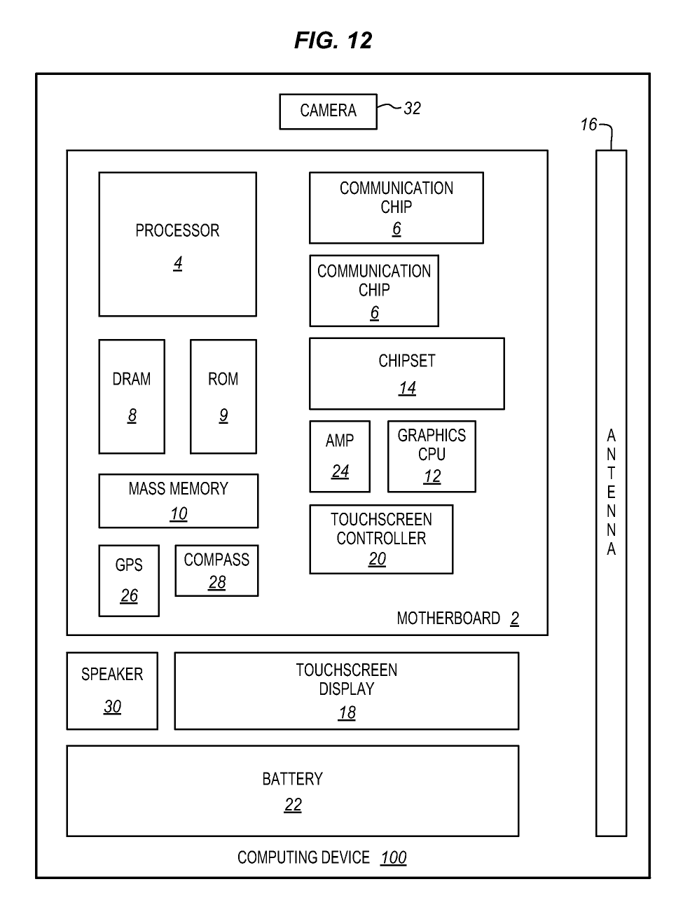

FIG. 12 illustrates a computing device 100 in accordance with one implementation of the invention. The computing device 100 houses a system board 2. The board 2 may include a number of components, including but not limited to a processor 4 and at least one communication package 6. The communication package is coupled to one or more antennas 16. The processor 4 is physically and electrically coupled to the board 2.

Depending on its applications, computing device 100 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth. These components may be connected to the system board 2, mounted to the system board, or combined with any of the other components.

The communication package 6 enables wireless and/or wired communications for the transfer of data to and from the computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication package 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 100 may include a plurality of communication packages 6. For instance, a first communication package 6 may be dedicated to shorter range wireless communications such as Wi-Fi and Bluetooth and a second communication package 6 may be dedicated to longer range wireless communications such as GPS, EDGE, GPRS, CDMA, WiMAX, LTE, Ev-DO, and others.

Any one or more of the chips may include dies that are fabricated with Ge NW MOS devices in the n or p well as described herein.

In various implementations, the computing device 100 may be a server, a workstation, a laptop, a netbook, a notebook, an ultrabook, a smartphone, a tablet, a personal digital assistant (PDA), an ultra mobile PC, a mobile phone, a printer, a scanner, a monitor, a set-top box, an entertainment control unit, a digital camera, a portable music player, or a digital video recorder. In further implementations, the computing device 100 may be any other electronic device, such as a pen, a wallet, a watch, or an appliance that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to an apparatus that includes a germanium nanowire formed on a substrate along a predetermined confinement orientation, a first doped region of the nanowire at a first end of the nanowire to define a source, a second doped region of the nanowire at a second end of the nanowire to define a drain, and a gate dielectric formed over the nanowire between the source and the drain.

In further embodiments the nanowire has a length at least three times greater than its diameter. The nanowire has a circular cross-section.

Further embodiments include a source contact at the first end of the nanowire to cover the circular cross-section and a drain contact at the second end to cover the circular cross section.

In further embodiments the nanowire has a polygonal cross-section.

Further embodiments include a source contact over the first end of the nanowire and a drain contact over the second end of the nanowire.

In further embodiments the nanowire has a carrier transport direction of x=<110> to cause a quantum confinement along the cross-section of the nanowire in the y-z plane. The germanium nanowire is an n-type formed by doping the source and the drain using n-type dopants.

Further embodiments include a second germanium nanowire formed on the substrate along the predetermined confinement orientation, a third p-type doped region of the second nanowire at a first end of the second nanowire to define a source, a fourth p-type doped region of the second nanowire at a second end of the second nanowire to define a drain, and a gate dielectric formed over the nanowire between the source and the drain of the second nanowire.

In further embodiments the substrate is a silicon substrate having a (100) surface and wherein the predetermined confinement orientation is formed of a <110> cut. In further embodiments, the first and second doped regions are part of an n-type complementary metal oxide semiconductor transistor and the first and second p-type doped regions are part of a p-type complementary metal oxide semiconductor transistor

Some embodiments pertain to a method that includes forming a dielectric on a substrate, forming a germanium nanowire on the substrate along a predetermined confinement orientation, doping a first region of the nanowire at a first end of the nanowire to define a source, doping a second region of the nanowire at a second end of the nanowire to define a drain, and forming a gate dielectric over the nanowire between the source and the drain.

In further embodiments the nanowire has a length at least three times greater than its diameter;

Further embodiments include forming a source contact at the first end to cover the first end of the nanowire and forming a drain contact at the second end to cover the second end of the nanowire.

In further embodiments the nanowire has a rectangular cross-section.

Further embodiments include a source contact over the first end of the nanowire and a drain contact over the second end of the nanowire.

In further embodiments the nanowire has a carrier transport direction of x=<110> to cause a quantum confinement along the cross-section of the nanowire in the y-z plane.

Further embodiments include forming the substrate by making a <110> cut on a silicon substrate having a (100) surface and wherein forming the germanium nanowire comprises forming the nanowire over the <110> cut.

Some embodiments pertain to a computing device that includes a processor, a memory, and a circuit board, wherein the processor comprises a dielectric layer over a silicon substrate and an nMOS device formed over the dielectric, the nMOS device comprising a germanium nanowire formed over the dielectric along a predetermined confinement orientation, a first doped region of the nanowire at a first end of the nanowire to define a source, a second doped region of the nanowire at a second end of the nanowire to define a drain, and a gate dielectric formed over the nanowire between the source and the drain.

In further embodiments the silicon substrate comprises n-wells and p-wells and wherein the dielectric is formed over at least one of the n-wells and p-wells.

In further embodiments the nMOS device further comprises a source contact at the first end of the nanowire to cover a circular cross-section of the nanowire and a drain contact at the second end to cover a circular cross section of the nanowire.

1. An apparatus comprising:
a germanium nanowire formed on a substrate along a predetermined confinement orientation;
a first doped region of the nanowire at a first end of the nanowire to define a source;
a second doped region of the nanowire at a second end of the nanowire to define a drain; and
a gate dielectric formed over the nanowire between the source and the drain.

2. The apparatus of claim 1, wherein the nanowire has a length at least three times greater than its diameter.

3. The apparatus of claim 1, wherein the nanowire has a circular cross-section.

4. The apparatus of claim 3, further comprising a source contact at the first end of the nanowire to cover the circular cross-section and a drain contact at the second end to cover the circular cross section.

5. The apparatus of claim 1, wherein the nanowire has a polygonal cross-section.

6. The apparatus of claim 5, further comprising a source contact over the first end of the nanowire and a drain contact over the second end of the nanowire.

7. The apparatus of claim 6, wherein the nanowire has a carrier transport direction of x=<110> to cause a quantum confinement along the cross-section of the nanowire in the y-z plane.

8. The apparatus of claim 7, wherein the germanium nanowire is an n-type formed by doping the source and the drain using n-type dopants.

9. The apparatus of claim 8, further comprising:
a second germanium nanowire formed on the substrate along the predetermined confinement orientation;
a first p-type doped region of the second nanowire at a first end of the second nanowire to define a source;
a second p-type doped region of the second nanowire at a second end of the second nanowire to define a drain; and
a gate dielectric formed over the nanowire between the source and the drain of the second nanowire.

10. The apparatus of claim 9, wherein the substrate is a silicon substrate having a (100) surface and wherein the predetermined confinement orientation is formed by a <110> cut.

11. The apparatus of claim 9, wherein the first and second doped regions are part of an n-type complementary metal oxide semiconductor transistor and the first and second p-type doped regions are part of a p-type complementary metal oxide semiconductor transistor.

12. A method comprising:
forming a dielectric on a substrate;
forming a germanium nanowire on the substrate along a predetermined confinement orientation;
doping a first region of the nanowire at a first end of the nanowire to define a source;
doping a second region of the nanowire at a second end of the nanowire to define a drain; and
forming a gate dielectric over the nanowire between the source and the drain.

13. The method of claim 12, wherein the nanowire has a length at least three times greater than its diameter.

14. The method of claim 12, further comprising forming a source contact at the first end to cover the first end of the nanowire and forming a drain contact at the second end to cover the second end of the nanowire.

15. The method of claim 12, wherein the nanowire has a rectangular cross-section.

16. The method of claim 15, further comprising a source contact over the first end of the nanowire and a drain contact over the second end of the nanowire.

17. The method of claim 12, wherein the nanowire has a carrier transport direction of x=<110> to cause a quantum confinement along the cross-section of the nanowire in the y-z plane.

18. The method of claim 12, further comprising forming the substrate by making a <110> cut on a silicon substrate having a (100) surface and wherein forming the germanium nanowire comprises forming the nanowire over the <110> cut.

19. A computing device comprising:
a processor;
a memory; and
a circuit board,
wherein the processor comprises a dielectric layer over a silicon substrate and an nMOS device formed over the dielectric, the nMOS device comprising a germanium nanowire formed over the dielectric along a predetermined confinement orientation, a first doped region of the nanowire at a first end of the nanowire to define a source, a second doped region of the nanowire at a second end of the nanowire to define a drain, and a gate dielectric formed over the nanowire between the source and the drain.

20. The computing device of claim 19, wherein the nMOS device further comprises a source contact at the first end of the nanowire to cover a circular cross-section of the nanowire and a drain contact at the second end to cover a circular cross section of the nanowire.
